(19) United States
(12) Patent Application Publication
(10) Pub. No.: US 2022/0165593 A1
(43) Pub. Date: May 26, 2022

(54) FEEDFORWARD CONTROL OF MULTI-LAYER STACKS DURING DEVICE FABRICATION

(71) Applicant: Applied Materials, Inc., Santa Clara, CA (US)

(72) Inventors: Priyadarshi Panda, Newark, CA (US); Lei Lian, Fremont, CA (US); Leonard Michael Tedeschi, San Jose, CA (US)

(21) Appl. No.: 17/103,847

(22) Filed: Nov. 24, 2020

(51) Int. Cl. H01L 21/67; H01L 27/108; G06N 3/08

(52) U.S. Cl. CPC H01L 21/67253; G06N 3/08; H01L 27/10885

(57) ABSTRACT

A method of forming a multi-layer stack on a substrate comprises: processing a substrate in a first process chamber using a first deposition process to deposit a first layer of a multi-layer stack on the substrate; removing the substrate from the first process chamber; measuring a first thickness of the first layer using an optical sensor; determining, based on the first thickness of the first layer, a target second thickness for a second layer of the multi-layer stack; determining one or more process parameter values for a second deposition process that will achieve the second target thickness for the second layer; and processing the substrate in a second process chamber using the second deposition process with the one or more process parameter values to deposit the second layer of the multi-layer stack approximately having the target second thickness over the first layer.

### TECHNICAL FIELD

Embodiments of the present disclosure relate to feedforward control of a multi-layer stack during device fabrication. Embodiments additionally relate to feedforward control of downstream processes in a multi-process fabrication sequence based on optical measurements performed after upstream processes in the multi-process fabrication sequence.

### BACKGROUND

To develop a manufacturing process sequence to form components on a substrate, engineers will perform one or more designs of experiments (DoEs) to determine process parameter values for each process in a sequence of processes to be performed in the manufacturing process sequence. For the DoEs, multiple different process parameter values are generally tested for each of the manufacturing processes by processing substrates using the different process parameter values for each manufacturing process. Devices or components that include one or more layers deposited and/or etched during the manufacturing process sequences are then tested at an end-of-line, where the end-of-line corresponds to completion of the component or device. Such testing results in one or more end-of-line performance metric values being determined. A result of the DoE(s) may be used to determine target process parameter values for process parameters of one or more of the manufacturing processes in the manufacturing process sequence and/or to determine target layer properties (also referred to herein as film properties) for layers deposited and/or etched by one or more of the manufacturing processes in the manufacturing process sequence.

Once the target process parameter values and/or target layer properties are determined, substrates will be processed according to the manufacturing process sequence, where predetermined process parameter values and/or layer properties that were determined based on an outcome of the DoEs are used for each process in the manufacturing process sequence. An engineer then expects processed substrates to have similar properties to those of substrates that were processed during the DoEs and further expects manufactured devices or components that include the layers formed by the manufacturing process sequence to have target end-of-line performance metric values. However, there is often variation between film properties determined during a DoE and film properties of films on product substrates, which results in changes to end-of-line performance metric values. Additionally, each process chamber may be slightly different from other process chambers, and may generate films having different film properties. Moreover, process chambers may change over time, causing films generated by those process chambers to also change over time, even if the same process recipe is used.

### SUMMARY

Some of the embodiments described herein cover a substrate processing system comprising at least one transfer chamber, a first process chamber connected to the at least one transfer chamber, a second process chamber connected to the at least one transfer chamber, an optical sensor configured to perform an optical measurement on the first layer after the first layer has been deposited on the substrate, and a computing device operatively connected to at least one of the first process chamber, the second process chamber, the transfer chamber or the optical sensor. The first process chamber is configured to perform a first process to deposit a first layer of a multi-layer stack on a substrate and the second process chamber is configured to perform a second process to deposit a second layer of the multi-layer stack on the substrate. The computing device is to receive a first optical measurement of the first layer after the first process has been performed on the substrate, wherein the first optical measurement indicates a first thickness of the first layer; determine, based on the first thickness of the first layer, a target second thickness for the second layer of the multi-layer stack; and cause the second process chamber to perform the second process to deposit the second layer approximately having the target second thickness onto the first layer.

In additional or related embodiments, a method comprises processing a substrate in a first process chamber using a first deposition process to deposit a first layer of a multi-layer stack on the substrate; removing the substrate from the first process chamber; measuring a first thickness of the first layer using an optical sensor; determining, based on the first thickness of the first layer, a target second thickness for a second layer of the multi-layer stack; determining one or more process parameter values for a second deposition process that will achieve the second target thickness for the second layer; and processing the substrate in a second process chamber using the second deposition process with the one or more process parameter values to deposit the second layer of the multi-layer stack approximately having the target second thickness over the first layer.

In some embodiments, a method comprises receiving or generating a training dataset comprising a plurality of data items, each data item of the plurality of data items comprising a combination of layer thicknesses for a plurality of layers of a multi-layer stack and an end-of-line performance metric value for a device comprising the multi-layer stack; and training, based on the training dataset, a machine learning model to receive a thickness of a single layer or thicknesses of at least two layers of the multi-layer stack as an input and to output at least one of a target thickness of a single remaining layer of the multi-layer stack, target thicknesses for at least two remaining layers of the multi-layer stack or a predicted end-of-line performance metric value for a device comprising the multi-layer stack.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1A is a top schematic view of a first example manufacturing system, according to an embodiment.

FIG. 1B is a top schematic view of a second manufacturing system, according to an embodiment.

FIG. 2A is a flow chart for a method of performing feedforward control of one or more processes in a DRAM bit line formation process, according to an embodiment.

FIG. 2B shows a schematic side view of a portion of a substrate including a poly plug, a DRAM bit line stack, and a hard mask layer, in accordance with an embodiment.

FIG. 3 illustrates a simplified side view of a system 300 for measuring thicknesses of layers on substrates in a cluster tool, according to one aspect of the disclosure.

FIG. 4 is a flow chart for a method of performing feedforward control of one or more downstream processes in a process sequence for a multi-layer stack based on optical measurements of films resulting from one or more already performed processes in the process sequence, according to an embodiment.

FIG. 5 is a flow chart for a method of performing feedforward control of a downstream etch process in a process sequence based on optical measurements of films resulting from one or more already performed deposition processes, according to an embodiment.

FIG. 6 is a flow chart for a method of performing feedforward control of one or more downstream processes in a process sequence based on optical measurements of films resulting from one or more already performed processes in the process sequence, according to an embodiment.

FIG. 7 is a flow chart for a method of updating a training of a machine learning model used to control downstream processes in a process sequence based on optical measurements of one or more layers formed by one or more processes in the process sequence.

FIG. 8 is a flow chart for a method of performing a design of experiments (DoE) associated with a manufacturing process sequence that forms one or more layers on a substrate, according to an embodiment.

FIG. 9 is a flow chart for a method of training a model to determine, based upon thickness values of one or more layers formed by one or more processes in a manufacturing process sequence, target thicknesses of one or more remaining layers, process parameter values for forming the one or more layers and/or end-of-line performance metric values, according to an embodiment.

FIG. 10 illustrates a diagrammatic representation of a machine in the example form of a computing device within which a set of instructions, for causing the machine to perform any one or more of the methodologies discussed herein, may be executed.

### DETAILED DESCRIPTION OF EMBODIMENTS

Embodiments described herein relate to methods of performing feedforward control of one or more yet to be performed processes in a manufacturing process sequence based on thickness measurements of one or more layers formed by one or more already performed processes in the manufacturing process sequence. In one embodiment, thicknesses of one or more already formed layers of a multi-layer stack are used to determine target thicknesses of one or more remaining layers to be formed for the multi-layer stack and/or process parameter values to achieve the target thicknesses. In one embodiment, thicknesses of one or more already formed layers on a substrate are used to determine target process parameter values to use for an etch process to be performed to etch the one or more already deposited layers. In embodiments, a trained machine learning model is used to determine, based on thicknesses of one or more layers, the thicknesses of additional layer(s) to be formed, process parameter values to be used to form the additional layer(s), process parameter values to be used to etch the already deposited layer(s) and/or a predicted end-of-line performance metric value for a device or component comprising the layer or layers. Embodiments also cover training of a machine learning model to determine, based on an input of one or more layer thicknesses, the thicknesses of additional layer(s) to be formed, process parameter values to be used to form the additional layer(s), process parameter values to be used to etch the already formed layer(s) and/or a predicted end-of-line performance metric value for a device or component comprising the layer or layers. Examples of machine learning models that may be trained include linear regression models, Gaussian regression models and neural networks, such as convolutional neural networks.

Traditionally, a one-time DoE is performed to determine the recipe set points for process parameters of each manufacturing process in a manufacturing process sequence (e.g., including a sequence of deposition processes and/or etch processes). Once the recipe set points are configured for each of the processes in a manufacturing process sequence, each process chamber that runs a recipe for a process in the manufacturing process sequence uses the determined process parameter set points for that process, and an assumption is made that the film quality and film properties that were determined at the time of the DoE are being achieved for the manufacturing process sequence. However, often there are variations between process chambers and/or process parameters of process chambers drift over time. Such variations and/or drift causes those process chambers to achieve different process parameter values than those that are actually set in a process recipe. For example, a process recipe for a manufacturing process may include a target temperature to 200° C., but a first process chamber may actually achieve a real temperature of 205° C. when set to 200° C. Additionally, a second process chamber may actually achieve a real temperature of 196° C. when set to 200° C. Such deviations from the predetermined process parameter values of the process recipe can cause one or more properties of a film deposited using the manufacturing process to vary from target properties. For example, two different chambers performing the same deposition process may form layers of different thicknesses, where a layer on a first substrate may have a thickness that is above a target thickness and the layer on a second substrate may have a thickness that is below the target thickness. The layer may be one layer of a multi-layer stack for a device that is ultimately formed, and such changes in the properties of the film can have detrimental effects on the devices that are ultimately formed.

For a multi-layer stack, if the thickness of a first layer of the multi-layer stack deviates from a target thickness, such deviation can cause detrimental effects to a device that includes the multi-layer stack. However, if the thickness deviation is detected before further layers of the multi-layer stack are deposited, then the target thicknesses of one or more of those further layers can be adjusted to cause the final multi-layer stack to have similar end-of-line performance metric values as the multi-layer stack would have had if the first layer were to have its target thickness. Similarly, if one or more of a first two layers in a multi-layer stack are detected to have thicknesses that deviate from target thicknesses before further layers are deposited, then this information can be used to adjust the target thicknesses for the one or more remaining layers in the multi-layer stack to improve the end-of line performance of the device that includes the multi-layer stack. In embodiments, an optical sensor is disposed in a transfer chamber, load lock or via, and is used to measure the thickness of deposited layers after deposition processes. The measured thicknesses may then be used to adjust future processes that will deposit additional layers and/or etch existing layers in a manner that increases an end-of-line performance of a device including the deposited layers.

In an example, the system and method described in embodiments herein can be used for providing feedforward control of one or more layers in a DRAM bit line stack. A DRAM bit line stack may include a barrier metal layer, a barrier layer, and a bit line metal layer. A sensing margin may be dependent on thicknesses of each of the barrier metal layer, the barrier layer and the bit line metal layer. A machine learning model may be trained to receive as an input a barrier metal layer thickness and/or the barrier layer thickness, and may output a target barrier layer thickness and/or bit line metal layer thickness. The machine learning model may additionally output a predicted sensing margin for the DRAM bit line stack including the barrier metal layer, barrier layer and bit line metal layer with the input and/or output thickness values. Thus, by measuring the thicknesses of the layers of the DRAM bit line stack after each layer is formed, a process used to form the next layer(s) may be adjusted at correct for any deviation of the already formed layers from target thicknesses for those layers. Such adjustments can improve the sensing margin for the DRAM memory module that includes the DRAM bit line stack. The same technique also works for any other type of multi-layer stack to improve other end-of-line performance metrics such as electrical properties of devices.

In embodiments, a computing device analyzes layers of a multi-layer stack and performs stack level optimization. Stack level information may be used to optimize power performance area and cost (PPAC) for devices including multi-layer stacks, for example. Feed forward decisions may be made for one unit process using information from one or more previous unit processes. Processing logic may use complex spectra from multiple unit processes as an input to one or more formed ML models, enabling optimization of the behavior of an entire stack as opposed to optimization of individual processes.

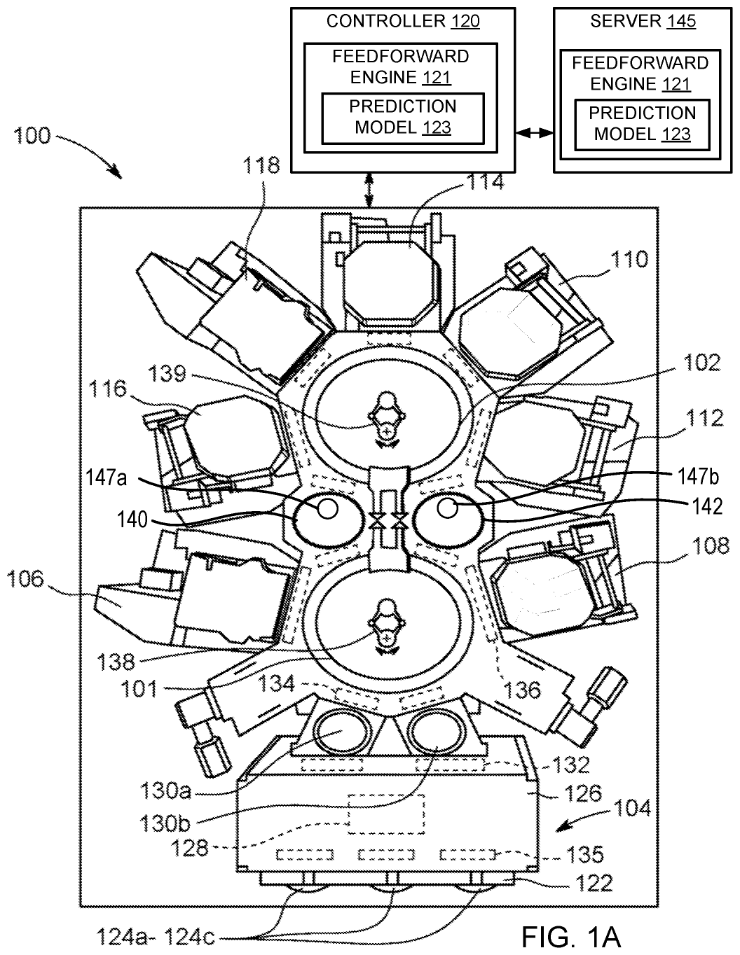

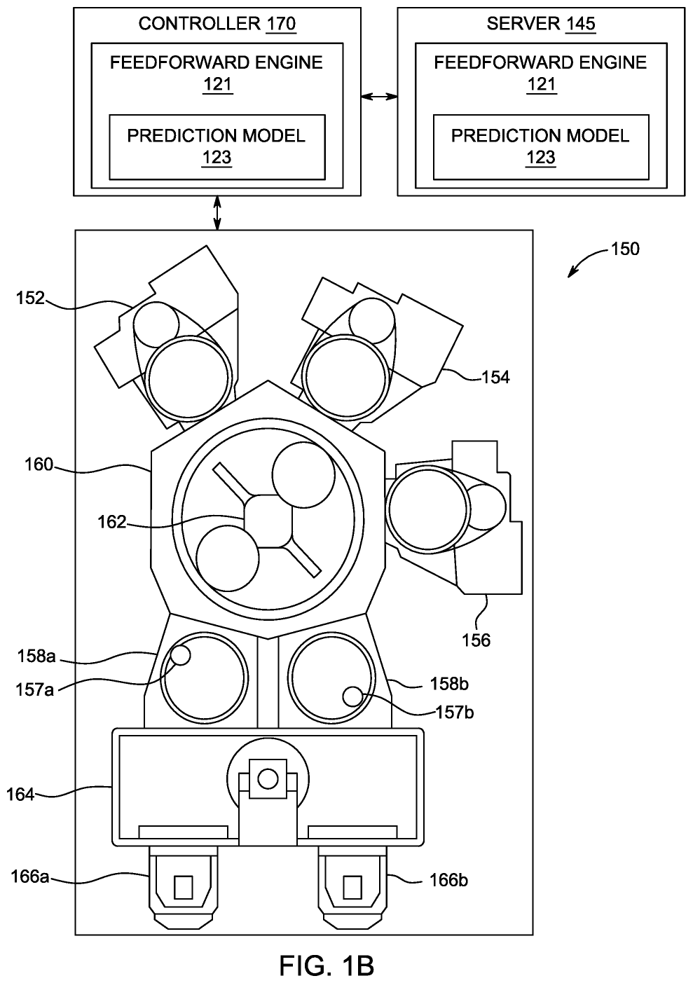

Referring now to the figures, FIG. 1A is a diagram of a cluster tool 100 (also referred to as a system or manufacturing system) that is configured for substrate fabrication, e.g., post poly plug fabrication, DRAM bit line formation, three-dimensional (3D) NAND formation (e.g., ONON gate formation and/or OPOP gate formation), etc. in accordance with at least some embodiments of the disclosure. The cluster tool 100 includes one or more vacuum transfer chambers (VTM) 101, 102, a factory interface 104, a plurality of processing chambers/modules 106, 108, 110, 112, 114, 116, and 118, and a process controller 120 (controller). A server computing device 145 may also be connected to the cluster tool 100 (e.g., to the controller 120 of the cluster tool 100). In embodiments with more than one VTM, such as is shown in FIG. 1A, one or more pass-through chambers (referred to as vias) may be provided to facilitate vacuum transfer from one VTM to another VTM. In embodiments consistent with that shown in FIG. 1A, two pass-through chambers can be provided (e.g., pass-through chamber 140 and pass-through chamber 142).

The factory interface 104 includes a loading port 122 that is configured to receive one or more substrates, for example from a front opening unified pod (FOUP) or other suitable substrate containing box or carrier, that are to be processed using the cluster tool 100. The loading port 122 can include one or multiple loading areas 124a-124c, which can be used for loading one or more substrates. Three loading areas are shown. However, greater or fewer loading areas can be used.

The factory interface 104 includes an atmospheric transfer module (ATM) 126 that is used to transfer a substrate that has been loaded into the loading port 122. More particularly, the ATM 126 includes one or more robot arms 128 (shown in phantom) that are configured to transfer the substrate from the loading areas 124a-124c to the ATM 126, through doors 135 (shown in phantom, also referred to as slit valves) that connects the ATM 126 to the loading port 122. There is typically one door for each loading port (124a-124c) to allow substrate transfer from respective loading port to the ATM 126. The robot arm 128 is also configured to transfer the substrate from the ATM 126 to load locks 130a, 130b through doors 132 (shown in phantom, one each for each load lock) that connect the ATM 126 to the air locks 130a, 130b. The number of load locks can be more or less than two but for illustration purposes only, two load locks (130a and 130b) are shown with each load lock having a door to connect it to the ATM 126. Load locks 130a-b may or may not be batch load locks.

The load locks 130a, 130b, under the control of the controller 120, can be maintained at either an atmospheric pressure environment or a vacuum pressure environment, and serve as an intermediary or temporary holding space for a substrate that is being transferred to/from the VTM 101, 102. The VTM 101 includes a robot arm 138 (shown in phantom) that is configured to transfer the substrate from the load locks 130a, 130b to one or more of the plurality of processing chambers 106, 108 (also referred to as process chambers), or to one or more pass-through chambers 140 and 142 (also referred to as vias), without vacuum break, i.e., while maintaining a vacuum pressure environment within the VTM 102 and the plurality of processing chambers 106, 108 and pass-through chambers 140 and 142. The VTM 102 includes a robot arm 138 (in phantom) that is configured to transfer the substrate from the air locks 130a, 130b to one or more of the plurality of processing chambers 106, 108, 110, 112, 114, 116, and 118, without vacuum break, i.e., while maintaining a vacuum pressure environment within the VTM 102 and the plurality of processing chambers 106, 108, 110, 112, 114, 116, and 118.

In certain embodiments, the load locks 130a, 130b can be omitted, and the controller 120 can be configured to move the substrate directly from the ATM 126 to the VTM 102.

A door 134, e.g., a slit valve door, connects each respective load lock 130a, 130b, to the VTM 101. Similarly, a door 136, e.g., a slit valve door, connects each processing module to the VTM to which the respective processing module is coupled (e.g., either the VTM 101 or the VTM 102). The plurality of processing chambers 106, 108, 110, 112, 114, 116, and 118 are configured to perform one or more processes. Examples of processes that may be performed by one or more of the processing chambers 106, 108, 110, 112, 114, 116, and 118 include cleaning processes (e.g., a pre-clean process that removes a surface oxide from a substrate), anneal processes, deposition processes (e.g., for deposition of a cap layer, a hard mask layer, a barrier layer, a bit line metal layer, a barrier metal layer, etc.), etch processes, and so on. Examples of deposition processes that may be performed by one or more of the process chambers include physical vapor deposition (PVD), chemical vapor deposition (CVD), atomic layer deposition (ALD), and so on. Examples of etch processes that may be performed by one or more of the process chambers include plasma etch processes. In one example embodiment, the process chambers 106, 108, 110, 112, 114, 116, and 118 are configured to perform processes that are typically associated with a post poly plug fabrication sequence and/or a dynamic random-access memory (DRAM) bit line stack fabrication sequence. In one example embodiment, the process chambers 106, 108, 110, 112, 114, 116, and 118 are configured to perform processes that are typically associated with a 3D NAND formation sequence, such as to form an ONON gate or an OPOP gate, which may include processes for depositing a multi-layer stack of alternating layers of an insulator and a conductor (e.g., of SiO₂ and SiN, or of SiO₂ and polysilicon).

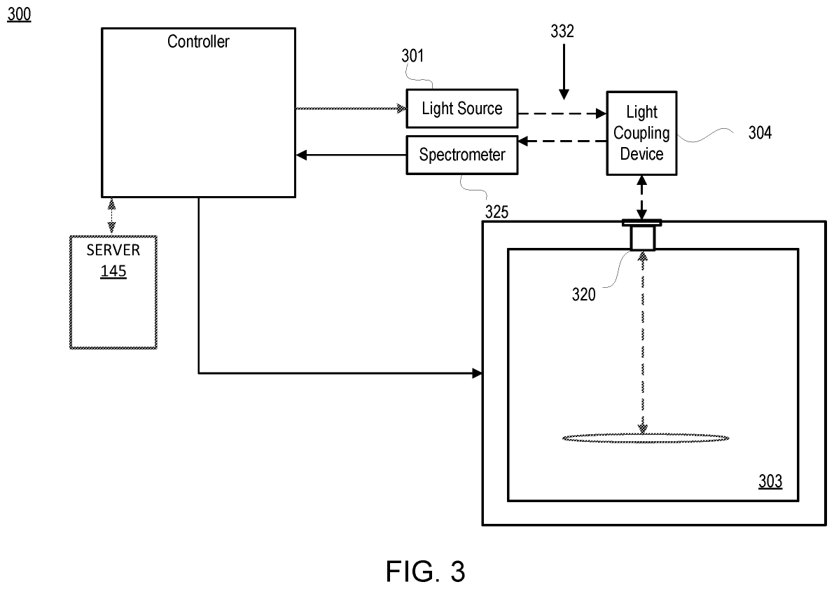

In embodiments, one or more of the components of cluster tool 100 include an optical sensor 147a, 147b configured to measure properties such as layer or film thickness on substrates. In one embodiment, optical sensor 147a is disposed in via 140 and optical sensor 147b is disposed in via 147b. Alternatively, or additionally, one or more optical sensors 147a-b may be disposed within VTM 102 and/or VTM 101. Alternatively, or additionally, one or more optical sensors 147a-b may be disposed in load lock 130a and/or load lock 130b. Alternatively, or additionally, one or more optical sensors 147a-b may be disposed in one or more of process chambers 106, 108, 110, 112, 114, 116, and 118. The optical sensor(s) 147a-b may be configured to measure film thickness of layers deposited on substrates. In one embodiment, the optical sensors 147a-b correspond to optical sensor 300 of FIG. 3. In some embodiments, an optical sensor 147a-b measures film thickness after each layer of a multi-layer stack is formed on a substrate. Optical sensor(s) 147a-b may measure film thickness between processes in a manufacturing process sequence, and may be used to inform decisions on how to perform further processes in the manufacturing process sequence. In embodiments, the optical measurements that indicate film thickness may be performed on substrates without removing the substrates from a vacuum environment.

Controller 120 (e.g., a tool and equipment controller) may control various aspects of the cluster tool 100, e.g., gas pressure in the processing chambers, individual gas flows, spatial flow ratios, plasma power in various process chambers, temperature of various chamber components, radio frequency (RF) or electrical state of the processing chambers, and so on. The controller 120 may receive signals from and send commands to any of the components of the cluster tool 100, such as the robot arms 128, 138, process chambers 106, 108, 110, 112, 114, 116, and 118, load locks 130a-b, slit valve doors, optical sensors 147a-b and/or one or more other sensors, and/or other processing components of the cluster tool 100. The controller 120 may thus control the initiation and cessation of processing, may adjust a deposition rate and/or target layer thickness, may adjust process temperatures, may adjust a type or mix of deposition composition, may adjust an etch rate, and the like. The controller 120 may further receive and process measurement data (e.g., optical measurement data) from various sensors (e.g., optical sensors 147a-b) and make decisions based on such measurement data.

In various embodiments, the controller 120 may be and/or include a computing device such as a personal computer, a server computer, a programmable logic controller (PLC), a microcontroller, and so on. The controller 120 may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. The controller 120 may include a data storage device (e.g., one or more disk drives and/or solid state drives), a main memory, a static memory, a network interface, and/or other components. The processing device of the controller 120 may execute instructions to perform any one or more of the methodologies and/or embodiments described herein. The instructions may be stored on a computer readable storage medium, which may include the main memory, static memory, secondary storage and/or processing device (during execution of the instructions).

In one embodiment, the controller 120 includes a feedforward engine 121. The feedforward engine 121 may be implemented in hardware, firmware, software, or a combination thereof. The feedforward engine 121 is configured to receive and process optical measurement data, optionally including the results of reflectometry performed by an optical sensor such as a spectrometer. The feedforward engine 121 may calculate the optical measurement data (e.g., a reflectometry signal) after a layer is formed on a substrate and/or after a layer on a substrate is etched to determine one or more target thickness values and/or other target properties for the layer. The feedforward engine 121 may further determine updated target thicknesses and/or other target properties for one or more additional layers of a multi-layer stack, may determine target process parameter values to use for a process for forming the layers having the updated target thicknesses and/or other properties, may determine target process parameter values for a process to use for etching one or more layers, and/or may predict one or more end-of-line performance metric values for a device or component that includes the layer. Examples of end-of-line performance metrics that may be measured include signal margin, yield, voltage, power, device speed of operation, device latency, and/or other performance variables.

In one embodiment, feedforward engine 121 includes a prediction model 123 that may correlate the film thickness and/or other film properties of one or more layers to a predicted value for an end-of-line performance metric. The prediction model 123 may additionally or alternatively output recommended target layer thicknesses and/or other target layer properties for to-be-deposited layers based on an input of thicknesses and/or other layer properties for one or more already deposited layers. Additionally, or alternatively, the prediction model 123 may output target process parameter values for process parameters for one or more yet to be performed processes in a manufacturing process sequence. The yet to be performed processes may be deposition processes and/or etch processes, for example. In one embodiment, the prediction model 123 is a trained machine learning model, such as a neural network, a Gaussian regression model or a linear regression model.

Feedforward engine 121 may input the measured thicknesses and/or other layer properties of one or more already formed layers into the prediction model 123, and may receive as an output target thicknesses and/or other target layer properties for one or more additional layers, target process parameter values for achieving the target thicknesses, target process parameter values for an etch process to be performed on the one or more layers and/or a predicted value for an end-of-line performance metric. Thereafter, the process recipes to be performed to form the additional layers and/or etch one or more layers may be adjusted based on the output of the prediction model 123. Thus, the feedforward engine 121 is able to predict end-of-line problems during the manufacturing process (i.e., before the end of the line is reached), and is further able to adjust one or more process recipes for yet-to-be performed processes in a manufacturing process sequence to avoid the predicted end-of-line problems.

In an example, a first one of the process chambers 106, 108, 110, 112, 114, 116, and 118 may be a deposition chamber that deposits a barrier metal layer, a second one of the process chambers may be a deposition chamber that deposits a barrier layer, and a third one of the process chambers may be a chamber that deposits a bit line metal layer. A manufacturing process sequence may include a first process recipe for depositing the barrier metal layer, a second process recipe for depositing the barrier layer and a third process recipe for depositing the bit line metal layer. Each of the process recipes may be associated with a target layer thickness to be achieved by the respective process recipe. The first deposition chamber may execute a process recipe to deposit the barrier metal layer. The optical sensor(s) 147a-b may be used to measure a thickness of the barrier metal layer. The feedforward engine 121 may then determine that the measured thickness deviates from a target thickness for the barrier metal layer. Feedforward engine 121 may use prediction model 123 to determine a new target thickness for the barrier layer and/or the bit line metal layer based on the measured thickness of the barrier metal layer. For example, if the barrier metal layer was too thick, then the barrier layer thickness and/or bit line metal layer thickness may be adjusted accordingly (e.g., by increasing and/or decreasing one or both of the barrier layer and bit line metal layer target thicknesses). New process parameter values for the process recipe for forming the barrier layer may be determined, and the second process chamber may perform the adjusted process recipe to form the barrier layer having the new target thickness.

The substrate may again be measured by an optical sensor 147a-b to determine a thickness of the barrier layer. The thickness of the barrier metal layer and the thickness of the barrier layer may then be compared to target thicknesses for these two layers to determine any deviations from the target thicknesses. If any such deviations are identified, then feedforward engine 121 may adjust the target thickness for the bit line metal layer. Feedforward engine 121 may use prediction model 123 to determine a new target thickness for the bit line metal layer based on the measured thicknesses of the barrier metal layer and the barrier layer. For example, if the barrier metal layer was too thick and the barrier layer was too thin, then the barrier layer thickness and/or bit line metal layer thickness may be adjusted accordingly (e.g., by increasing and/or decreasing one or both of the barrier layer and bit line metal layer target thicknesses). New process parameter values for the process recipe for forming the metal bit line layer may be determined, and the third process chamber may perform the adjusted process recipe to form the metal bit line layer having the new target thickness.

The substrate may again be measured by an optical sensor 147a-b to determine a thickness of the metal bit line layer. The thicknesses of the metal barrier layer, the barrier layer and the metal bit line layer may then be used by feedforward engine 121 to predict a value for an end-of-line performance metric. If the predicted value deviates from a specification, a determination may be made to scrap the substrate rather than spending additional resources to complete fabrication of a device or component that is predicted to fail final inspection. Additionally, or alternatively, the process chamber that deposited a layer that is too thick or too thin may be taken out of service and/or scheduled for maintenance if the end-of-line performance metric value is below a performance threshold. Accordingly, feedforward engine 121 may perform diagnostics on the health of a process chamber and schedule the process chamber for maintenance when appropriate.

Controller 120 may be operatively connected to server 145. Server 145 may be or include a computing device that operates as a factory floor server that interfaces with some or all tools in a fabrication facility. Server 145 may send instructions to controllers of one or more cluster tools, such as cluster tool 100. For example, server 145 may receive signals from and send commands to controller 120 of cluster tool 100.

In various embodiments, the server 145 may be and/or include a computing device such as a personal computer, a server computer, a programmable logic controller (PLC), a microcontroller, and so on. The server 145 may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. The server 145 may include a data storage device (e.g., one or more disk drives and/or solid state drives), a main memory, a static memory, a network interface, and/or other components. The processing device of the server 145 may execute instructions to perform any one or more of the methodologies and/or embodiments described herein. The instructions may be stored on a computer readable storage medium, which may include the main memory, static memory, secondary storage and/or processing device (during execution of the instructions).

In some embodiments, server 145 include feedforward engine 121 and prediction model 123. Server 145 may include feedforward engine 121 and prediction model 123 in addition to or instead of controller 120 including feedforward engine 121 and prediction model 123. In some embodiments, controller 120 and/or server 145 correspond to computing device 1000 of FIG. 10.

In some instances, one or more processes may be performed on a substrate in a first cluster tool (e.g., cluster tool 100) to form one or more films on the substrate, and one or more processes may be performed on the substrate in another cluster tool (e.g., an etch process performed optionally after performing a lithography process on the substrate). Optical measurements may be performed in the first cluster tool and/or the second cluster tool to determine predicted end-of-line performance and/or to make adjustments for one or more further processes to be performed on the substrate. In such an embodiment, server 145 may communicate with controllers of both cluster tools to coordinate the feedforward control of the yet to be performed process or processes in a manufacturing process sequence based on measured thicknesses of one or more layers formed on the substrate through already performed processes in the manufacturing process sequence.

FIG. 1B is a diagram of a cluster tool 150 that is configured for substrate fabrication, e.g., post poly plug fabrication, in accordance with at least some embodiments of the disclosure. The cluster tool 150 includes a vacuum transfer chamber (VTM) 160, a factory interface 164, a plurality of chambers/modules 152, 154, 156 (some or all of which may be process chambers), and a controller 170. Server computing device 145 may also be connected to the cluster tool 150 (e.g., to the controller 170 of the cluster tool 150).

The factory interface 164 includes one or more loading port that is configured to receive one or more substrates, for example from a front opening unified pod (FOUP) 166a, 166b or other suitable substrate containing box or carrier, that are to be processed using the cluster tool 150.

The factory interface 164 includes an atmospheric transfer module (ATM) that is used to transfer a substrate that has been loaded into the loading port. More particularly, the ATM includes one or more robot arms that are configured to transfer the substrate from loading areas to the ATM, through that connect the ATM to the loading port. The robot arm is also configured to transfer the substrate from the ATM to load locks 158a-b through doors that connect the ATM to the load locks 158a-b. The load locks 158a-b, under the control of the controller 170, can be maintained at either an atmospheric pressure environment or a vacuum pressure environment, and serve as an intermediary or temporary holding space for a substrate that is being transferred to/from the VTM 160. The VTM 160 includes a robot arm 162 that is configured to transfer the substrate from the load locks 158a-b to one or more of the plurality of processing chambers 152, 154, 156, without vacuum break, i.e., while maintaining a vacuum pressure environment within the VTM 160 and the plurality of chambers 152, 154, 156.

In the illustrated embodiment, optical sensors 157a-b are disposed in load locks 158a-b, respectively, for performing optical measurements on substrates passing through the load locks 158a-b. Alternatively, or additionally, one or more optical sensors may be disposed in VTM 160 and/or in one of chambers 152, 154, 156.

Controller 170 (e.g., a tool and equipment controller) may control various aspects of the cluster tool 150, e.g., gas pressure in the processing chambers, individual gas flows, spatial flow ratios, temperature of various chamber components, radio frequency (RF) or electrical state of the processing chambers, and so on. The controller 170 may receive signals from and send commands to any of the components of the cluster tool 150, such as the robot arms 162, process chambers 152, 154, 156, load locks 158a-b, optical sensors 157a-b, slit valve doors, one or more sensors, and/or other processing components of the cluster tool 150. The controller 170 may thus control the initiation and cessation of processing, may adjust a deposition rate, a type or mix of deposition composition, an etch rate, and the like. The controller 170 may further receive and process measurement data (e.g., optical measurement data) from various sensors such as optical sensors 157a-b. The controller 170 may be substantially similar to controller 120 of FIG. 1A, and may include a feedforward engine 121 (e.g., that may include a prediction model 123).

Controller 170 may be operatively connected to server 145, which may also be operatively connected to controller 120 of FIG. 1A.

In an example, one or more processes are performed on a substrate by various process chambers 106, 116, 118, 114, 110, 112, 108 of cluster tool 100 to form one or more layers on the substrate. Thicknesses of the one or more layers may be measured using optical sensor(s) 147a-b. The measured thicknesses may be used by feedforward engine 121 to determine layer thicknesses for one or more to-be-deposited layers, process parameters for processes for forming the to-be-deposited layers and/or process parameter values for processes to etch the already deposited layers. The substrate may then be removed from cluster tool 100 and placed in a lithography tool to pattern a mask layer on the substrate. The substrate may then be placed into cluster tool 150. One or more etch processes may then performed on the substrate by one or more of process chambers 152, 154, 156 of cluster tool 150 to etch the film or films. One or more target process parameter values for the etch process may have been output by the feedforward engine 121 based on the measured thickness or thicknesses of deposited layer(s). Alternatively, or additionally, one or more deposition processes may be performed on the substrate by one or more of process chambers 152, 154, 156 of cluster tool 150 to deposit one or more layer of a multi-layer stack. The target thicknesses for such films may have been output by the feedforward engine 121 based on the measured thickness or thicknesses of deposited layer(s).

In one embodiment, the process chambers of cluster tool 100 and/or cluster tool 150 are configured to perform one or more DRAM bit line stack processes (e.g., for post poly plug fabrication). Alternatively, the cluster tool 100 and/or cluster tool 150 may be configured to perform other processes, such as 3D NAND deposition processes.

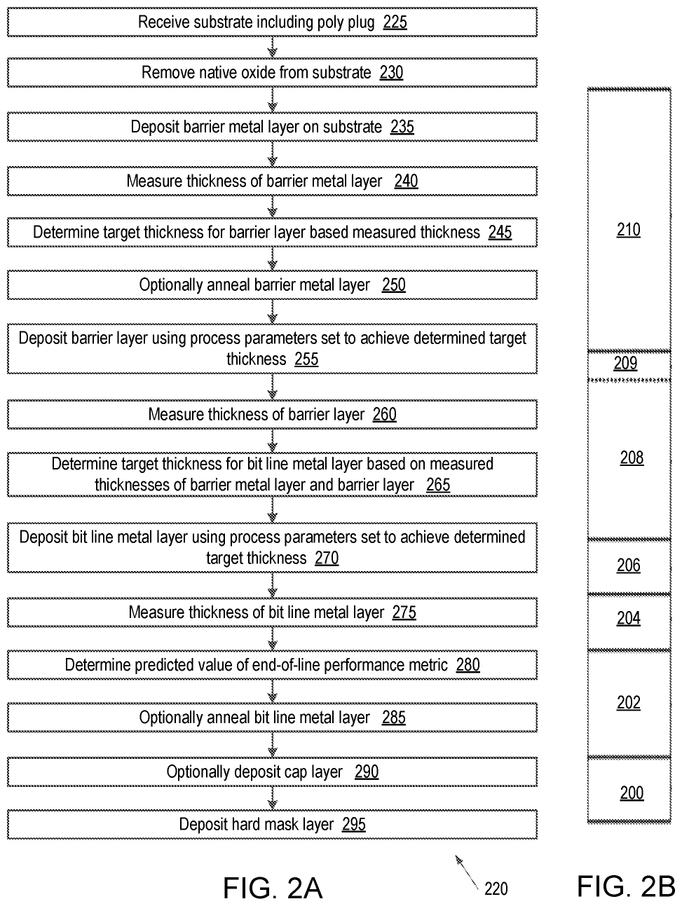

FIG. 2A is a flow chart for a method 220 of performing feedforward control of one or more processes in a DRAM bit line formation process, according to an embodiment. FIG. 2B shows a schematic side view of a portion of a substrate 200 including a poly plug 202, a DRAM bit line stack 201 (including a barrier metal 204, a barrier layer 206, and a bit line metal layer 208), and a hard mask layer 210, according to an embodiment. The poly plug 202 may have been formed outside of cluster tool 100. The DRAM bit line stack 201 may be formed inside of the cluster tool 100 without breaking a vacuum between deposition of the various layers of the DRAM bit line stack 201, according to method 220.

At operation 225 of method 220, substrate 200 can be loaded into the loading port 122, via one or more of the loading areas 124a-124c. The robot arm 128 of the ATM 126, under control of the controller 120, can transfer the substrate 200 having the poly plug 202 from the loading area 124a to the ATM 126. Robot arm 128 can then place the substrate 200 into a load lock 130a-b, and the load lock can be pumped down to vacuum under control of controller 120. The controller 120 can then instruct the robot arm 138 to transfer the substrate 300 to one or more of the processing chambers so that fabrication of the substrate 200 can be completed—i.e., completion of the bit line stack processes atop the poly plug 202 on the substrate 200.

At operation 230, robot arm 138, under control of controller 120, can retrieve the substrate 200 from the load lock 130a-b and place the substrate into a pre-cleaning chamber (e.g., process chamber 106). Transfer of the substrate 200 from the load lock to the process chamber 106 can be performed without a vacuum break (i.e., the vacuum pressure environment is maintained within the VTM 101 and the VTM 102 while the substrate 200 is transferred to the pre-cleaning chamber). The processing chamber 106 can be used to perform one or more pre-cleaning process to remove contaminants that may be present on the substrate 200, e.g., native oxidation that can be present on the substrate 200.

At operation 235, the controller 120 opens the door 136 and instructs the robot arm 138 to transfer the substrate 200 to the next processing chamber, which may be a barrier metal deposition chamber, such as process chamber 108. Transfer of the substrate 200 from the process chamber 106 to the process chamber 108 can be performed without a vacuum break. The process chamber then performs a deposition process to form barrier metal layer 204 over the poly plug 202. The barrier metal can be one of titanium (Ti) or tantalum (Ta), for example.

At operation 240, controller 120 instructs robot arm 138 to remove the substrate 200 from process chamber 108 and instructs an optical sensor 147a-b to generate an optical measurement of barrier metal layer 204 to determine a thickness of the barrier metal layer 204. For example, the controller 120 can instruct the robot arm 138 to transfer the substrate under vacuum from the processing chamber 108 to either of the pass through chambers 140, 142. The controller 120 can instruct an optical sensor 147a-b to generate an optical measurement of the barrier metal layer 204 while the substrate 200 is in the pass through chamber 140, 142.

At operation 245, controller 120 determines a target thickness for barrier layer 206 based on the measured thickness of barrier metal layer 202. Additionally, controller 120 may determine a target thickness of bit line metal layer 208. Determinations of the target thickness for the barrier layer and/or barrier metal layer may be made using feedforward engine 121 and/or a trained machine learning model such as prediction model 123, for example. Operations 240, 245 can be performed without a vacuum break for the substrate 200.

In one embodiment, at operation 250 controller 120 instructs robot arm 139 to transfer substrate 200 to another process chamber (e.g., process chamber 116), without a vacuum break, and instructs the process chamber to perform an anneal operation on the barrier metal layer 204. In some embodiments, operations 240 and/or 245 may be performed after operation 250. The annealing process can be any suitable annealing process, such as a rapid thermal processing (RTP) anneal.

At operation 255, the controller 120 can instruct the robot arm 139 to transfer, without vacuum break, the substrate 200 from the pass through chamber 140, 142 or from the anneal process chamber (e.g., process chamber 116) to a barrier layer deposition chamber (e.g., process chamber 110). The processing chamber 110, for example, may be configured to perform a barrier layer deposition process on the substrate 200 (e.g., to deposit a barrier layer 206 atop the barrier metal layer 204). The barrier layer 206 can be one of titanium nitride (TiN), tantalum nitride (TaN), or tungsten nitride (WN), for example.

At operation 260, controller 120 instructs robot arm 138 or robot arm 139 to remove the substrate 200 from the barrier layer deposition chamber and instructs an optical sensor 147a-b to generate an optical measurement of barrier layer 206 to determine a thickness of the barrier layer 206. For example, the controller 120 can instruct the robot arm 139 to transfer the substrate under vacuum from the processing chamber 108 to either of the pass through chambers 140, 142. The controller 120 can instruct an optical sensor 147a-b to generate an optical measurement of the barrier layer 206 while the substrate 200 is in the pass through chamber 140, 142.

At operation 265, controller 120 determines a target thickness for bit line metal layer 208 based on the measured thickness of barrier layer 206 and the measured thickness of barrier metal layer 204. Determination of the target thickness for the bit line metal layer 208 may be made using feedforward engine 121 and/or a trained machine learning model such as prediction model 123, for example. Operations 260, 265 can be performed without a vacuum break for the substrate 200.

At operation 270, the controller 120 can instruct the robot arm 139 to transfer, without vacuum break, the substrate 200 from the processing chamber 110 to, for example, the bit line metal deposition process chamber (e.g., processing chamber 112). The bit line metal deposition chamber may be configured to perform a bit line metal deposition process on the substrate 200 (e.g., to deposit a bit line metal layer 208 atop the barrier layer 206). The bit line metal layer can be one of tungsten (W), molybdenum (Mo), ruthenium (Ru), iridium (Ir), or rhodium (Rh), for example.

At operation 275, controller 120 instructs robot arm 139 to remove the substrate 200 from the bit line metal layer deposition chamber and instructs an optical sensor 147a-b to generate an optical measurement of bit line metal layer 208 to determine a thickness of the bit line metal layer 208. For example, the controller 120 can instruct the robot arm 139 to transfer the substrate under vacuum from the processing chamber 112 to either of the pass through chambers 140, 142. The controller 120 can instruct an optical sensor 147a-b to generate an optical measurement of the bit line metal layer 208 while the substrate 200 is in the pass through chamber 140, 142.

At operation 280, controller 120 predicts a value for an end-of-line performance metric based on the measured thickness of the metal bit line layer 208, the measured thickness of barrier layer 206 and the measured thickness of barrier metal layer 204. Determination of the end-of-line performance metric value may be made using feedforward engine 121 and/or a trained machine learning model such as prediction model 123, for example. Operations 275, 280 can be performed without a vacuum break for the substrate 200.

In one embodiment, at operation 285 controller 120 instructs robot arm 139 to transfer substrate 200 to an annealing process chamber (e.g., process chamber 116), without a vacuum break, and instructs the process chamber to perform an anneal operation on the bit line metal layer 208. In some embodiments, operations 275 and/or 280 may be performed after operation 285. The annealing process can be any suitable annealing process, such as a rapid thermal processing (RTP) anneal.

In some embodiments where the annealing process is performed at operation 285, at operation 290 the annealed substrate 200 can be transferred to another processing chamber to have an optional capping layer 209 deposited on the bit line metal layer 208. For example, the annealed substrate 200 including the bit line metal layer 208 can be transferred under vacuum from the annealing chamber (e.g., processing chamber 116) to a capping layer deposition chamber (e.g., processing chamber 118), e.g., using the robot arm 139, to deposit a capping layer atop the annealed bit line metal layer 208.

At operation 295, the controller 120 can instruct the robot arm 139 to transfer, without vacuum break, the substrate 200 to a hard mask deposition chamber (e.g., such as processing chamber 114). The hard mask deposition chamber is configured to perform a hard mask deposition process on the substrate 200 (e.g., to deposit a hard mask layer 210 atop the bit line metal layer 208 and/or the cap layer 209). The hard mask can be one of silicon nitride (SiN), silicon oxide (SiO), or silicon carbide (SiC), for example.

By performing each of the above sequences in an integrated tool (e.g., the cluster tool 100), oxidation of the bit line metal during anneal for grain growth is further advantageously avoided.

After the DRAM bit line stack and hard mask layer 210 have been formed, substrate 200 may be removed from cluster tool 100 and processed using a lithography tool to form a pattern in the hard mask 210. The substrate may then be transferred to cluster tool 150, which may perform one or more etch processes to etch one or more layers of the DRAM bit line stack. In some embodiments, at operation 280 the controller 120 further determines one or more process parameter values for an etch process to be performed on the DRAM bit line stack based on the thicknesses of the metal barrier layer, barrier layer and/or metal bit line layer. These process parameter values may be communicated to controller 170. The controller 170 may then instruct an etch process chamber (e.g., process chamber 152 or 154) to perform the etch process using the determined etch process parameter value(s).

Method 220 may result in a DRAM bit line stack with improved end-of-line performance properties as compared to DRAM bit line stacks formed using conventional processing techniques.

FIG. 3 illustrates a simplified side view of an optical sensor system 300 for measuring thicknesses of layers on substrates in a cluster tool, according to one aspect of the disclosure. The optical sensor system may correspond, for example, to optical sensors 147a-b, 157-b of FIGS. 1A-B in embodiments. The system 300 may include, for example, a chamber 303, which may be a transfer chamber (e.g., VTM 101, 102), a load lock chamber 130a-b, a pass through chamber 140, 142, or other chamber of a cluster tool. In one embodiment, the chamber 303 is a measurement chamber attached to a facet of a cluster tool (e.g., to a facet of a VTM).

The chamber 303 may include an interior volume that is at a vacuum pressure, which may be part of a vacuum environment of one or more VTMs (e.g., VTM 101, 102). The chamber 303 may include a window 320. Window 320 may be, for example, a transparent crystal, glass or another transparent material. The transparent crystal may be made of transparent ceramic material, or may be made of a durable transparent material such as sapphire, diamond, quartz, silicon carbide, or a combination thereof.

In embodiments, the system 300 further includes a light source 301 (e.g., a broadband light source or other source of electromagnetic radiation), a light coupling device 304 (e.g., a collimator or a mirror), a spectrometer 325, the controller 120, 170, and optionally the server 145. The light source 301 and spectrometer 325 may be optically coupled to the light coupling device 304 through one or more fiber optic cable 332.

In various embodiments, the light coupling device 304 may be adapted to collimate or otherwise transmit light in two directions along an optical path. A first direction may include light from the light source 301 that is to be collimated and transmitted into the chamber 303 through the window 320. A second direction may be reflected light that has reflected off of a substrate 304 and back through the window 320 that passes back into the light coupling device 304. The reflected light may be focused into the fiber optic cable 332 and thus directed to the spectrometer 325 in the second direction along the optical path. Further, the fiber optic cable 332 may be coupled between the spectrometer 325 and the light source 301 for efficient transfer of light between the light source 301, to the transparent crystal 120, and back to the spectrometer 325.

In an embodiment, the light source emits light at a spectrum of about 200-800 nm, and the spectrometer 325 also has a 200-800 nm wavelength range. The spectrometer 325 may be adapted to detect a spectrum of the reflected light received from the light coupling device 304, e.g., the light that has reflected off of a substrate in chamber 303 and back through the window 320 and been focused by the light coupling device 304 into the fiber optic cable 332.

The controller 120, 170 may be coupled to both the light source 301, the spectrometer 325, and the chamber 303.

In one embodiment, the controller 120, 170 may direct the light source 301 to flash on and then receive a light spectrum from the spectrometer 325. The controller 120, 170 may also keep the light source off and receive a second spectrum from the spectrometer 325 when the light source 301 is off. The controller 120, 170 may subtract the second spectrum from the first spectrum to determine the reflectometry signal for a moment in time. The controller 120, 170 may then mathematically fit the reflectometry signal to one or more thin film models to determine one or more optical thin film property of a film that is measured.

In some embodiments, the one or more optical thin film property may include film thickness, a refractive index (n), and/or an extinction coefficient (k) value. The refractive index is the ratio of the speed of light in a vacuum to the speed of light in the film. The extinction coefficient is a measure of how much light is absorbed in the film. The controller 120, 170 may determine, using the n and k values, a composition of the film. The controller 120, 170 may further be configured to analyze the data of the one or more property of the film. The controller 120, 170 may then determine target thickness values for layers to be deposited, target process parameter values for deposition processes and/or etch processes, and/or end-of-line performance properties as discussed herein above using a feedforward engine. Alternatively, server 145 may determine target process parameter values for deposition processes and/or etch processes, and/or end-of-line performance properties as discussed herein above using a feedforward engine.

Note that embodiments are discussed herein with reference using a particular property of one or more layers (i.e., thickness) to determine target thicknesses of additional layers, process parameter values for additional processes to be performed and/or end-of-line performance properties. However, it should be understood that other layer properties of deposited layers that can be determined based on an optical measurement (e.g., such as refractive index n and/or extinction coefficient k) can be used instead of or in addition to thickness to determine target thicknesses of additional layers, process parameter values for additional processes to be performed and/or end-of-line performance properties. Accordingly, it should be understood that any reference to use of thickness measurements herein applies to use of thickness measurements alone or use of thickness measurements together with refractive index and/or extinction coefficient. Additionally, it should be understood that other optically measureable film properties such as index of refraction and/or extinction coefficient may be substituted for thickness measurement in embodiments herein.

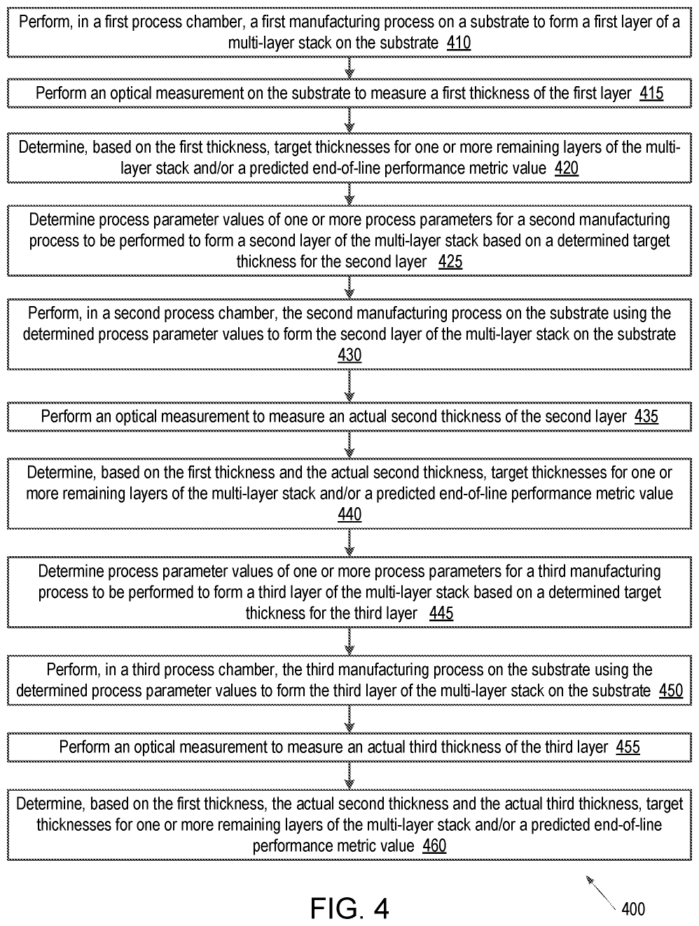

FIG. 4 is a flow chart for a method 400 of performing feedforward control of one or more downstream processes in a process sequence for a multi-layer stack based on optical measurements of films resulting from one or more already performed processes in the process sequence, according to an embodiment.

At operation 410 of method 400, a first manufacturing process is performed on a substrate in a first process chamber to form a first layer of a multi-layer stack on the substrate. In some embodiments, there are additional layers on the substrate under the first layer. The substrate may then be removed from the process chamber.

At operation 415, an optical sensor is used to perform an optical measurement on the substrate to measure a first thickness of the first layer. Additionally, or alternatively, one or more other properties of first layer may be measured using the optical sensor, such as index of refraction and/or extinction coefficient.

At operation 420, a computing device (e.g., a controller or server) determines, based on the first thickness (and/or the one or more other measured properties of the first layer) a target thickness for one or more remaining layers of the multi-layer stack. Additionally, or alternatively, the computing device may determine one or more other target properties for the one or more remaining layers (e.g., such as target index of refraction, target surface roughness, target average grain size, target grain orientation, etc.) based on the first thickness (and/or one or more other measured properties of the first layer). Additionally, or alternatively, at operation 420 the computing device may determine target process parameter values for the processes that will be performed to form the one or more remaining layers. For example, the computing device may determine process parameter values for process parameters such as deposition time, gas flow rates, temperature, pressure, plasma power, etc. for one or more deposition processes to be performed that will approximately result in a determined target layer thickness. Additionally, the computing device may predict one or more end-of-line performance metric values for a device or component that includes the multi-layer stack with the measured thickness and with the target thicknesses of the one or more remaining layers. If the predicted end-of-line performance metric value is below a performance threshold, then the substrate may be scrapped or reworked in some embodiments. Additionally or alternatively, a process chamber that deposited the first layer may be scheduled for maintenance if the predicted end-of-line performance metric value is below a performance threshold. Operation 420 may be performed by inputting the measured thickness (and/or other properties) of the first layer into prediction model 123 in embodiments.

At operation 425, processing logic determines process parameter values of one or more process parameters for a second manufacturing process to be performed to form a second layer of the multi-layer stack. In one embodiment, the process parameter values are determined by inputting the target thickness (and/or other target properties of the next layer to be deposited) into a table, function or model. The table, function or model may receive a target thickness (and/or other layer properties), and may output the process parameter values. In one embodiment, the model is a trained machine learning model such as a neural network (e.g., a convolutional neural network) or a regression model that has been trained to output process parameter values for a recipe based on an input target thickness and/or other input target properties for the layer. In one embodiment, the target process parameter values were determined at operation 420.

At operation 430, the substrate is transferred to a second process chamber, and the second process chamber performs a second manufacturing process on the substrate using the determined process parameter values to form the second layer of the multi-layer stack on the substrate. The substrate may then be removed from the second process chamber.

At operation 435, an optical sensor is used to perform an optical measurement on the substrate to measure an actual second thickness of the second layer. Additionally, or alternatively, one or more other properties of second layer may be measured using the optical sensor, such as index of refraction and/or extinction coefficient.

At operation 440, the computing device (e.g., controller or server) determines, based on the first thickness of the first layer and the actual second thickness of the second layer (and/or the one or more other measured properties of the first layer and second layer) a target thickness for one or more remaining layers of the multi-layer stack. Additionally, or alternatively, the computing device may determine one or more other target properties for the one or more remaining layers (e.g., such as target index of refraction, target surface roughness, target average grain size, target grain orientation, etc.) based on the first thickness (and/or one or more other measured properties of the first layer) and actual second thickness (and/or one or more other measured properties of the second layer). Additionally, or alternatively, at operation 440 the computing device may determine target process parameter values for the processes that will be performed to form the one or more remaining layers. For example, the computing device may determine process parameter values for process parameters such as deposition time, gas flow rates, temperature, pressure, plasma power, etc. for one or more deposition processes to be performed that will approximately result in a determined target layer thickness. Additionally, the computing device may predict one or more end-of-line performance metric values for a device or component that includes the multi-layer stack with the measured first thickness and second thickness with the target thicknesses of the one or more remaining layers. If the predicted end-of-line performance metric value is below a performance threshold, then the substrate may be scrapped or reworked and/or the second process chamber may be scheduled for maintenance in some embodiments. Operation 440 may be performed by inputting the measured thicknesses (and/or other properties) of the first and second layers into prediction model 123 in embodiments. In some embodiments, the same trained machine learning model is used at operations 420 and 440. Alternatively, different trained machine learning models may be used at operations 420 and 440. For example, the trained machine learning model used at operation 420 may be trained to receive only a single thickness and the trained machine learning model used at operation 440 may be trained to receive two thickness values.

In one embodiment, in which the multi-layer stack includes two layers, at operation 440 the computing device determines the predicted end-of-line performance metric value, but does not determine target thicknesses for any remaining layers. In such an embodiment, method 400 may end at operation 440.

At operation 445, processing logic may determine process parameter values of one or more process parameters for a third manufacturing process to be performed to form a third layer of the multi-layer stack. In one embodiment, the process parameter values are determined by inputting the target thickness (and/or other target properties of the next layer to be deposited) into a table, function or model. The table, function or model may receive a target thickness (and/or other layer properties), and may output the process parameter values. In one embodiment, the model is a trained machine learning model such as a neural network (e.g., a convolutional neural network) or a regression model that has been trained to output process parameter values for a recipe based on an input target thickness and/or other input target properties for the layer. In one embodiment, the target process parameter values were determined at operation 440.

At operation 450, the substrate is transferred to a third process chamber, and the third process chamber performs a third manufacturing process on the substrate using the determined process parameter values to form the third layer of the multi-layer stack on the substrate. The substrate may then be removed from the third process chamber.

At operation 455, an optical sensor is used to perform an optical measurement on the substrate to measure an actual third thickness of the third layer. Additionally, or alternatively, one or more other properties of third layer may be measured using the optical sensor, such as index of refraction and/or extinction coefficient.

At operation 460, the computing device (e.g., controller or server) determines, based on the first thickness of the first layer, the measured second thickness of the second layer and the measured third thickness of the third layer (and/or the one or more other measured properties of the first layer, second layer and third layer) predicted end-of-line performance metric value. If the end-of-line performance metric value is below a performance threshold, then the substrate may be scrapped or reworked in some embodiments. Operation 460 may be performed by inputting the measured thicknesses (and/or other properties) of the first, second and third layers into prediction model 123 in embodiments. In some embodiments, the same trained machine learning model is used at operations 420, 440 and 460. Alternatively, different trained machine learning models may be used at operations 420, 440 and 460. If there are additional layers to be deposited after the third layer, then at operation 460 the computing device may additionally or alternatively determine a target thickness for the next layer and/or target process parameter values for achieving the target thickness. Similar operations to operations 450-460 may then be performed for the next layer.

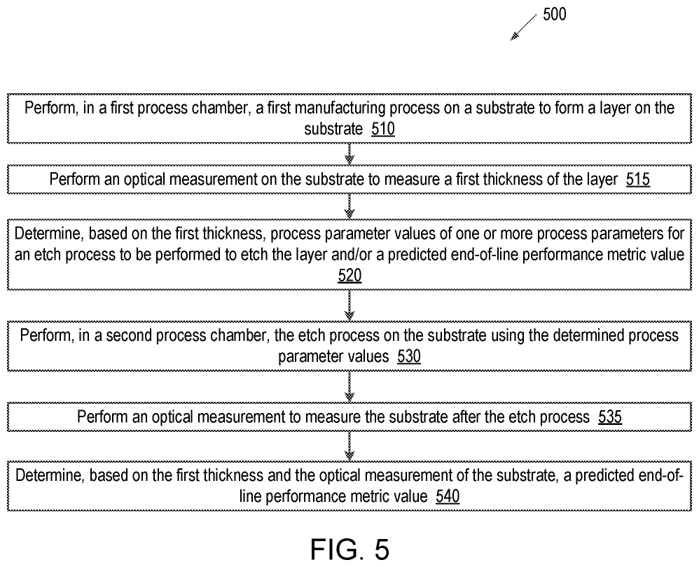

FIG. 5 is a flow chart for a method 500 of performing feedforward control of a downstream etch process in a process sequence based on optical measurements of films resulting from one or more already performed deposition processes, according to an embodiment.

At operation 510 of method 500, a first manufacturing process is performed on a substrate in a first process chamber to form a layer on the substrate. In some embodiments, there are additional layers on the substrate under the first layer. In some embodiments, the layer is a layer of a multi-layer stack. The substrate may then be removed from the process chamber.

At operation 515, an optical sensor is used to perform an optical measurement on the substrate to measure a first thickness of the first layer. Additionally, or alternatively, one or more other properties of the first layer may be measured using the optical sensor, such as index of refraction and/or extinction coefficient.

At operation 520, a computing device (e.g., a controller or server) determines, based on the first thickness (and/or the one or more other measured properties of the first layer), target process parameter values for one or more process parameters of an etch process to be performed on the deposited layer. Additionally, the computing device may predict one or more end-of-line performance metric values for a device or component that includes the layer. If the predicted end-of-line performance metric value is below a performance threshold, then the substrate may be scrapped or reworked and/or the process chamber may be scheduled for maintenance in some embodiments. Operation 520 may be performed by inputting the measured thickness (and/or other properties) of the layer into prediction model 123 in embodiments.

At operation 530, the substrate is transferred to a second process chamber (e.g., an etch process chamber), and the second process chamber performs an etch process on the substrate using the determined process parameter values to etch the layer. In an example, the layer deposited at operation 510 may have been thicker than a target thickness, and the etch time for the etch process may be increased to accommodate the thicker layer. The substrate may then be removed from the second process chamber.

At operation 535, an optical sensor is optionally used to perform an optical measurement on the substrate to measure a post etch thickness of the layer. Additionally, or alternatively, one or more other post etch properties of layer may be measured using the optical sensor.

At operation 540, the computing device (e.g., controller or server) may determine, based on the thickness of the layer and/or the post etch thickness of the layer (and/or the one or more other measured properties of the layer), a predicted end-of-line performance metric value. If the predicted end-of-line performance metric value is below a performance threshold, then the substrate may be scrapped or reworked in some embodiments. Operation 540 may be performed by inputting the measured thicknesses (and/or other properties) of the layer into prediction model 123 in embodiments. In some embodiments, the same trained machine learning model is used at operations 520 and 540. Alternatively, different trained machine learning models may be used at operations 520 and 540.

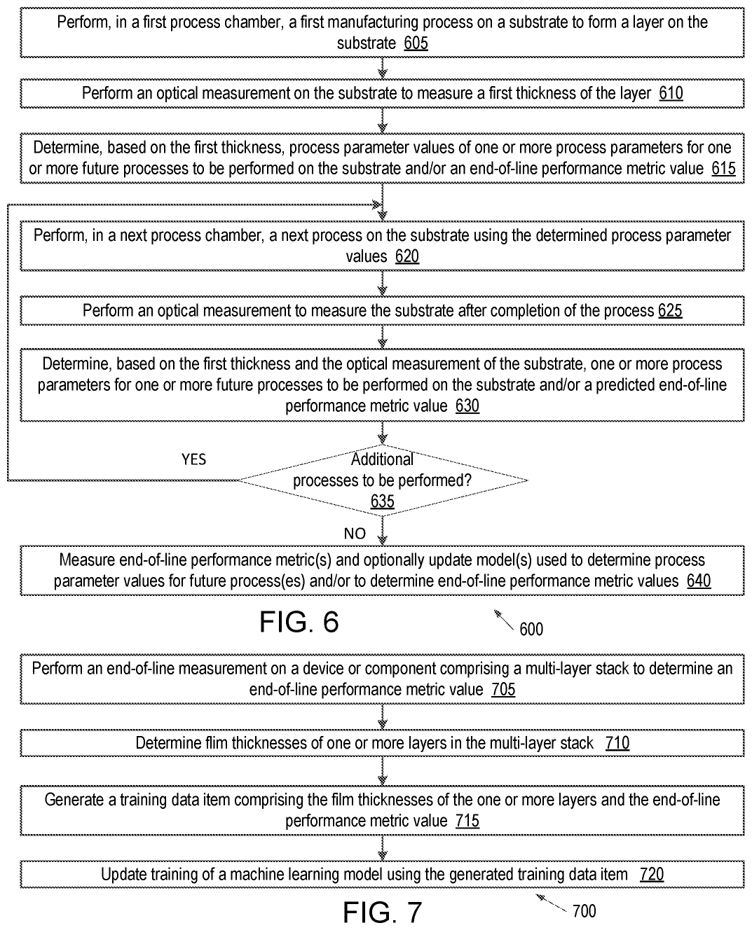

FIG. 6 is a flow chart for a method 600 of performing feedforward control of one or more downstream processes in a process sequence based on optical measurements of films resulting from one or more already performed processes in the process sequence, according to an embodiment.

At operation 605 of method 600, a first manufacturing process is performed on a substrate in a first process chamber to form a layer on the substrate. In some embodiments, there are additional layers on the substrate under the first layer.

At operation 610, an optical sensor is used to perform an optical measurement on the substrate to measure a first thickness of the first layer. Additionally, or alternatively, one or more other properties of the first layer may be measured using the optical sensor, such as index of refraction and/or extinction coefficient.

At operation 615, a computing device (e.g., a controller or server) determines, based on the first thickness (and/or the one or more other measured properties of the first layer) one or more process parameter values for one or more process parameters for one or more future processes to be performed on the substrate. If further layers are to be deposited on the substrate, the computing device may optionally also determine a target thickness for one or more remaining layers. Additionally, or alternatively, the computing device may determine one or more other target properties for the one or more remaining layers (e.g., such as target index of refraction, target surface roughness, target average grain size, target grain orientation, etc.) based on the first thickness (and/or one or more other measured properties of the first layer). Additionally, the computing device may predict one or more end-of-line performance metric values for a device or component that includes the first layer with the measured thickness. If the predicted end-of-line performance metric value is below a performance threshold, then the substrate may be scrapped or reworked and/or the process chamber that deposited the first layer on the substrate may be scheduled for maintenance in some embodiments. Operation 615 may be performed by inputting the measured thickness (and/or other properties) of the first layer into prediction model 123 in embodiments.

At operation 620, the substrate is transferred to a second process chamber, and the second process chamber performs a second manufacturing process on the substrate using the determined process parameter values. The second manufacturing process may be, for example, a deposition process, an etch process, an anneal process, or some other process. For example, the second manufacturing process may be a deposition process to form the second layer of a multi-layer stack on the substrate.

At operation 625, an optical sensor may be used to perform an optical measurement on the substrate after completion of the second manufacturing process. If the second process was a deposition process, then the optical measurement may measure one or more properties (e.g., a thickness) of the additional deposited layer.

At operation 630, the computing device (e.g., controller or server) may determine, based on the first thickness of the first layer and the optical measurements of the substrate determined at operation 625 (e.g., a second thickness of a second layer), one or more process parameter values for process parameters of one or more further processes to be performed on the substrate. Additionally, or alternatively, the computing device may determine a predicted value for an end-of-line performance metric. If the predicted end-of-line performance metric value is below a performance threshold, then the substrate may be scrapped or reworked and/or the second process chamber may be scheduled for maintenance in some embodiments. Operation 630 may be performed by inputting the measured thicknesses (and/or other properties) of the first and/or second layers into prediction model 123 in embodiments.

At operation 635, processing logic determines whether additional processes are to be performed whose results are to be measured using an optical sensor. If so, the method returns to block 620, and a next process is performed in a next process chamber. Otherwise, the method proceeds to operation 640. At operation 640, once a device or component is complete (or has reached a stage of completion at which one or more performance metrics can be measured), a measurement is made to determine an end-of-line performance metric. For example, a sensing margin and/or other electrical properties of a device may be measured. The results of the measured end-of-line performance metric value along with the measurement results determined at operations 610 and/or 625 may then be used to further train a machine learning model that was used at operations 615 and 630. For example, prediction model 123 may be continually trained as new product lots are completed. As a result, the accuracy of prediction model 123 may continue to improve over time.

FIG. 7 is a flow chart for a method 700 of updating a training of a machine learning model used to control downstream processes in a process sequence based on optical measurements of one or more layers formed by one or more processes in the process sequence. Method 700 may be used, for example, to periodically retrain prediction model 123. Method 700 may be performed by processing logic, which may include hardware, software, firmware, or a combination thereof. In embodiments, method 700 is performed by a controller 120, 170 and/or server 145 of FIGS. 1A-B.

At operation 705 of method 700, an end-of-line measurement is made on a device or component that includes a multi-layer stack to determine an end-of-line performance metric value. At operation 710, processing logic determines film thicknesses of one or more layers in the multi-layer stack. The thicknesses of each respective layer may have been measured after deposition of that layer. For example, the layer thicknesses may have been measured according to any of methods 400-600. At operation 715, processing logic generates a training data item comprising the film thicknesses of the one or more layers and the end-of-line performance metric value. At operation 720, processing logic then performs supervised learning on a trained machine learning model (e.g., prediction model 123) using the training data item to update the training of the machine learning model.

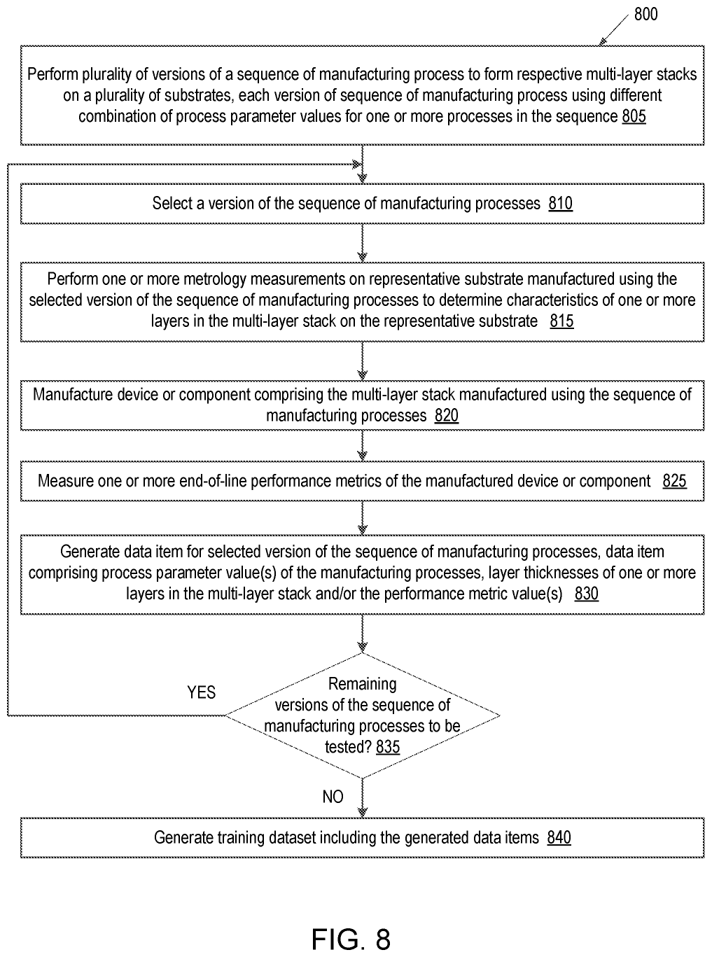

FIG. 8 is a flow chart for a method 800 of performing a design of experiments (DoE) associated with a manufacturing process sequence that forms one or more layers on a substrate, according to an embodiment. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are performed in every embodiment. Other process flows are possible.

At operation 805 of method 800, a plurality of versions of a sequence of manufacturing processes are performed. Each version of the sequence of manufacturing processes uses a different combination of process parameter values for one or more processes in the sequence and results in a multi-layer stack having a different combination of layer thicknesses. In one embodiment, the multi-layer stack is a DRAM bit line stack, and each version of the DRAM bit line stack has a different combination of layer thicknesses for a barrier metal layer, a barrier layer and a bit line metal layer. In some instances, an optimal value for a combination of layer thicknesses for the multi-layer stack may be known a priori, and that optimal combination of layer thicknesses as well as one or more additional combinations of layer thicknesses in which one or more of the layer thicknesses are above and/or below the optimal thicknesses may be tested. For example, for a DRAM bit line stack the optimal layer thicknesses may be 2 nm for the metal barrier layer, 3 nm for the barrier layer and 20 nm for the metal bit line layer. Different versions of the DRAM bit line stack may be generated, where some versions vary just one of the thicknesses above or below the optimal thickness, some versions vary two of the thicknesses above and/or below the optimal thicknesses and some versions vary all three of the thicknesses above and/or below the optimal thicknesses. In one example, about 300 substrates are processed to produce multi-layer stacks with a range of thickness combinations. For each of the versions of the sequence of manufacturing processes, one or more further processes may be performed on the substrates to produce a testable device or component.

At operation 810, one of the versions of the manufacturing process sequence is selected.

At operation 815, one or more metrology measurements are performed on a representative substrate manufactured using the selected version of the sequence of manufacturing processes to determine characteristics of one or more layers of the multi-layer stack on the representative substrate. For example, a destructive metrology measurement may be performed to determine the thickness of each layer of a multi-layer stack on the substrate. Alternatively, measurements may be made in-line during manufacturing of the multi-layer stack (e.g., by performing a non-destructive optical measurement of each layer of the multi-layer stack after the layer is formed).

At operation 820, a device or component may be manufactured using a substrate with a multi-layer stack formed using the selected sequence of manufacturing processes. In some embodiments, operation 820 is performed before operation 810. Examples of devices that may be formed include DRAM memory modules and 3D NAND memory modules.

At operation 825, one or more end of line performance metrics are measured for the manufactured device or component that includes the multi-layer stack formed by the selected version of the manufacturing process. The performance metrics may include sensing margin, voltage, power, device speed, device latency, yield, and/or other performance parameters. In some embodiments, one or more electrical measurements are performed on the device or component to determine one or more electrical properties of the device or component. The electrical properties may correspond to or be end-of-line performance metrics for the device or component. For example, sensing margin is a percentage of the voltage that is delivered to a gate for a memory unit that is actually detected by the gate. Larger sensing margins are superior to smaller sensing margins, because devices with a larger sensing margin can function using less voltage (e.g., a smaller voltage can be applied to a gate of the memory unit to change a state of the gate).

At operation 830, a data item is generated for the selected version of the sequence of manufacturing processes. The data item may be a training data item that includes the layer thicknesses for each layer in the multi-layer stack and the end-of-line performance metric value(s).

At operation 835, a determination is made as to whether there are remaining versions of the sequence of manufacturing processes that have not yet been tested (and for which data items have not yet been generated). If there are still remaining untested versions of the sequence of manufacturing processes, the method returns to operation 810, and a new version of the sequence of manufacturing processes is selected to be tested. If all of the versions of the sequence of manufacturing processes have been tested, the method continues to operation 840.

At operation 840, a training dataset is generated. The training dataset includes the data items generated for each of the versions of the sequence of manufacturing processes.

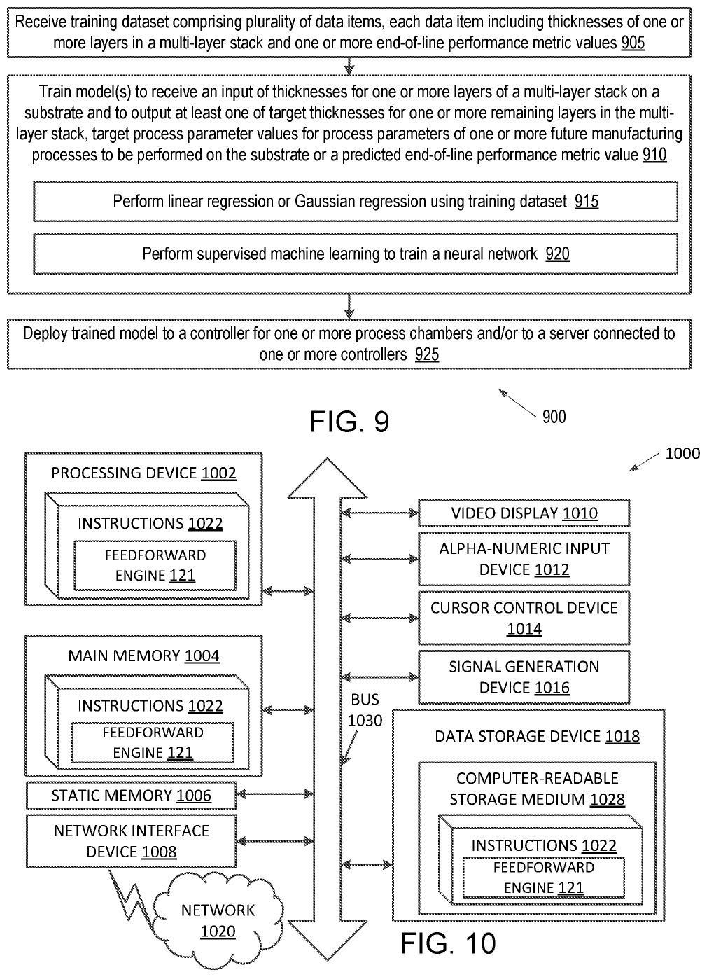

FIG. 9 is a flow chart for a method 900 of training a model to determine, based upon thickness values of one or more layers formed by one or more processes in a manufacturing process sequence, target thicknesses of one or more remaining layers, process parameter values for forming the one or more layers and/or end-of-line performance metric values, according to an embodiment. The method 900 may be performed with the components described with reference to FIGS. 1A-3, as will be apparent. For example, method 900 may be performed by controller 120, controller 170 and/or server 145 in embodiments. At least some operations of method 900 may be performed by a processing logic that may comprise hardware (e.g., circuitry, dedicated logic, programmable logic, microcode, etc.), software (e.g., instructions run on a processing device to perform hardware simulation), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are performed in every embodiment. Other process flows are possible.

At operation 905 of method 900, processing logic receives a training dataset (e.g., which may have been generated according to method 800). The training dataset may include a plurality of data items, where each data item includes one or more layer thicknesses of a version of a sequence of manufacturing processes and an end-of-line performance metric value.

At operation 910, processing logic trains a model to receive an input of thicknesses for one or more layers of a multi-layer stack on a substrate and to output at least one of target thicknesses for one or more remaining layers in the multi-layer stack, target process parameter values for process parameters of one or more future manufacturing processes to be performed on the substrate and/or a predicted end-of-line performance metric value.

In one embodiment, the model is a machine learning model such as a regression model trained using regression. Examples of regression models are regression models trained using linear regression or Gaussian regression. In one embodiment, at operation 915 processing logic performs linear regression or Gaussian regression using the training dataset to train the model. A regression model predicts a value of Y given known values of X variables. The regression model may be trained using regression analysis, which may include interpolation and/or extrapolation. In one embodiment, parameters of the regression model are estimated using least squares. Alternatively, Bayesian linear regression, percentage regression, leas absolute deviations, nonparametric regression, scenario optimization and/or distance metric learning may be performed to train the regression model.

In one embodiment, the model is a machine learning model, such as an artificial neural network (also referred to simply as a neural network). The artificial neural network may be, for example, a convolutional neural network (CNN) or a deep neural network. In one embodiment, at operation 920 processing logic performs supervised machine learning to train the neural network.

Artificial neural networks generally include a feature representation component with a classifier or regression layers that map features to a target output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). The neural network may be a deep network with multiple hidden layers or a shallow network with zero or a few (e.g., 1-2) hidden layers. Deep learning is a class of machine learning algorithms that use a cascade of multiple layers of nonlinear processing units for feature extraction and transformation. Each successive layer uses the output from the previous layer as input. Neural networks may learn in a supervised (e.g., classification) and/or unsupervised (e.g., pattern analysis) manner. Some neural networks (e.g., such as deep neural networks) include a hierarchy of layers, where the different layers learn different levels of representations that correspond to different levels of abstraction. In deep learning, each level learns to transform its input data into a slightly more abstract and composite representation.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset. In high-dimensional settings, such as large images, this generalization is achieved when a sufficiently large and diverse training dataset is made available.

In embodiments, the inputs are feature vectors including film properties of one or more layers (e.g., such as film thicknesses), and the labels are performance metric values such as end-of-line performance metric values (e.g., electrical values such as sensing margin). In one embodiment, the neural network is trained to receive film properties of one or more deposited layers as an input and to output one or more predicted performance metric values, film properties for yet to be deposited layers and/or process parameter values for future processes to be performed on the already deposited layers and/or to deposit further layers.

At operation 925, the trained model is deployed. The trained model may be deployed to a controller of one or more process chambers and/or cluster tools, for example. Additionally, or alternatively, the trained model may be deployed to a server connected to one or more controllers (e.g., to controllers of one or more process chambers and/or of one or more cluster tools). Deploying the trained model may include saving the trained model in a feedforward engine of the controller and/or server. Once the trained model is deployed, the controller and/or server may use the trained model to perform feedforward control of one or more manufacturing processes in a sequence of manufacturing processes.

FIG. 10 illustrates a diagrammatic representation of a machine in the example form of a computing device 1000 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The example computing device 1000 includes a processing device 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory (e.g., a data storage device 1018), which communicate with each other via a bus 1030.

Processing device 1002 represents one or more general-purpose processors such as a microprocessor, central processing unit, or the like. More particularly, the processing device 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1002 may also be one or more special-purpose processing devices such as an application specific integrated circuit (ASIC), a field programmable gate array (FPGA), a digital signal processor (DSP), network processor, or the like. Processing device 1002 is configured to execute the processing logic (instructions 1022) for performing the operations and steps discussed herein.

The computing device 1000 may further include a network interface device 1008. The computing device 1000 also may include a video display unit 1010 (e.g., a liquid crystal display (LCD) or a cathode ray tube (CRT)), an alphanumeric input device 1012 (e.g., a keyboard), a cursor control device 1014 (e.g., a mouse), and a signal generation device 1016 (e.g., a speaker).

The data storage device 1018 may include a machine-readable storage medium (or more specifically a computer-readable storage medium) 1028 on which is stored one or more sets of instructions 1022 embodying any one or more of the methodologies or functions described herein. The instructions 1022 may also reside, completely or at least partially, within the main memory 1004 and/or within the processing device 1002 during execution thereof by the computer system 1000, the main memory 1004 and the processing device 1002 also constituting computer-readable storage media.

The computer-readable storage medium 1028 may also be used to store a feedforward engine 121, and/or a software library containing methods that call a feedforward engine 121. While the computer-readable storage medium 1028 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies described herein. The term “computer-readable storage medium” shall accordingly be taken to include, but not be limited to, non-transitory computer readable media such as solid-state memories, and optical and magnetic media.

The modules, components and other features described herein (for example in relation to FIGS. 1A-3) can be implemented as discrete hardware components or integrated in the functionality of hardware components such as ASICS, FPGAs, DSPs or similar devices. In addition, the modules can be implemented as firmware or functional circuitry within hardware devices. Further, the modules can be implemented in any combination of hardware devices and software components, or only in software.

Some portions of the detailed description have been presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a target result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving”, “identifying”, “determining”, “selecting”, “providing”, “storing”, or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the present invention also relate to an apparatus for performing the operations herein. This apparatus may be specially constructed for the discussed purposes, or it may comprise a general purpose computer system selectively programmed by a computer program stored in the computer system. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A substrate processing system comprising:
at least one transfer chamber;
a first process chamber connected to the at least one transfer chamber, wherein the first process chamber is configured to perform a first process to deposit a first layer of a multi-layer stack on a substrate;
a second process chamber connected to the at least one transfer chamber, wherein the second process chamber is configured to perform a second process to deposit a second layer of the multi-layer stack on the substrate;
an optical sensor configured to perform an optical measurement on the first layer after the first layer has been deposited on the substrate; and
a computing device operatively connected to at least one of the first process chamber, the second process chamber, the transfer chamber or the optical sensor, wherein the computing device is to:
receive a first optical measurement of the first layer after the first process has been performed on the substrate, wherein the first optical measurement indicates a first thickness of the first layer;
determine, based on the first thickness of the first layer, a target second thickness for the second layer of the multi-layer stack; and
cause the second process chamber to perform the second process to deposit the second layer approximately having the target second thickness onto the first layer.

2. The substrate processing system of claim 1, further comprising:
a third process chamber connected to the at least one transfer chamber, wherein the third process chamber is configured to perform a third process to deposit a third layer of the multi-layer stack on the substrate;
wherein the optical sensor is further configured to perform the optical measurement on the second layer; and
wherein the computing device is further to:
receive a second optical measurement of the second layer after the second process has been performed on the substrate, wherein the second optical measurement indicates a an actual second thickness of the second layer;
determine, based on the first thickness of the first layer and the actual second thickness of the second layer, a target third thickness for the third layer of the multi-layer stack; and
cause the third process chamber to perform the third process to deposit the third layer approximately having the target third thickness onto the second layer.

3. The substrate processing system of claim 2, wherein in order to determine the target third thickness for the third layer of the multi-layer stack, the computing device is to:
input the first thickness of the first layer and the actual second thickness of the second layer into a trained machine learning model that has been trained to determine, for an input of the first thickness of the first layer and the actual second thickness of the second layer, the target third thickness of the third layer that, when combined with the first thickness of the first layer and the actual second thickness of the second layer, results in an optimal end-of-line performance metric value for a device comprising the multi-layer stack.

4. The substrate processing system of claim 2, wherein:
the optical sensor is further configured to perform the optical measurement on the third layer; and
the computing device is further to:
receive a third optical measurement of the third layer after the third process has been performed on the substrate, wherein the third optical measurement indicates an actual third thickness of the third layer; and
determine, based on the first thickness of the first layer, the actual second thickness of the second layer, and the actual third thickness of the third layer, a predicted end-of-line performance metric value for a device comprising the multi-layer stack.

5. The substrate processing system of claim 4, wherein in order to determine the predicted end-of-line performance metric value for the device comprising the multi-layer stack, the computing device is to:
input the first thickness of the first layer, the actual second thickness of the second layer and the actual third thickness of the third layer into a trained machine learning model that has been trained to predict, for an input of the first thickness of the first layer, the actual second thickness of the second layer and the actual third thickness of the third layer, the predicted end-of-line performance metric value for the device comprising the multi-layer stack.

6. The substrate processing system of claim 5, wherein the multi-layer stack comprises a dynamic random access memory (DRAM) bit line stack, and wherein the predicted end-of-line performance metric value comprises a sensing margin.

7. The substrate processing system of claim 1, wherein in order to determine the target second thickness for the second layer of the multi-layer stack, the computing device is to:
input the first thickness of the first layer into a trained machine learning model that has been trained to output, for an input of the first thickness of the first layer, the target second thickness of the second layer that, when combined with the first thickness of the first layer, results in an optimal end-of-line performance metric value for a device comprising the multi-layer stack.

8. The substrate processing system of claim 7, wherein the trained machine learning model comprises a neural network.

9. The substrate processing system of claim 7, wherein the trained machine learning model is further trained to output at least one of a target third thickness of a third layer of the multi-layer stack or an end-of-line performance metric value for a device comprising the multi-layer stack.

10. The substrate processing system of claim 1, wherein the optical sensor comprises a spectrometer configured to measure the first thickness using reflectometry.

11. The substrate processing system of claim 1, wherein the optical sensor is a component of the transfer chamber, a load lock chamber or a pass-through station connected to the transfer chamber.

12. A method comprising:
processing a substrate in a first process chamber using a first deposition process to deposit a first layer of a multi-layer stack on the substrate;
removing the substrate from the first process chamber;
measuring a first thickness of the first layer using an optical sensor;
determining, based on the first thickness of the first layer, a target second thickness for a second layer of the multi-layer stack;
determining one or more process parameter values for a second deposition process that will achieve the second target thickness for the second layer; and
processing the substrate in a second process chamber using the second deposition process with the one or more process parameter values to deposit the second layer of the multi-layer stack approximately having the target second thickness over the first layer.

13. The method of claim 12, further comprising:
measuring an actual second thickness of the second layer using the optical sensor or an additional optical sensor;
determining, based on the first thickness of the first layer and the actual second thickness of the second layer, a target third thickness for a third layer of the multi-layer stack;
determining one or more additional process parameter values for a third deposition process that will achieve the third target thickness for the second layer; and
processing the substrate in a third process chamber using the one or more additional process parameter values to perform the third deposition process to deposit the third layer approximately having the target third thickness onto the second layer.

14. The method of claim 13, wherein determining the target third thickness for the third layer of the multi-layer stack comprises:
inputting the first thickness of the first layer and the actual second thickness of the second layer into a trained machine learning model that has been trained to output, for an input of the first thickness of the first layer and the actual second thickness of the second layer, the target third thickness of the third layer that, when combined with the first thickness of the first layer and the actual second thickness of the second layer, results in an optimal end-of-line performance metric value for a device comprising the multi-layer stack.

15. The method of claim 13, further comprising:
measuring an actual third thickness of the third layer using the optical sensor or the additional optical sensor; and
determining, based on the first thickness of the first layer, the actual second thickness of the second layer, and the actual third thickness of the third layer, a predicted end-of-line performance metric value for a device comprising the multi-layer stack.

16. The method of claim 15, wherein determining the predicted end-of-line performance metric value for the device comprising the multi-layer stack comprises:
inputting the first thickness of the first layer, the actual second thickness of the second layer and the actual third thickness of the third layer into a trained machine learning model that has been trained to predict, for an input of the first thickness of the first layer, the actual second thickness of the second layer and the actual third thickness of the third layer, the predicted end-of-line performance metric value for the device comprising the multi-layer stack.

17. The method of claim 16, wherein the multi-layer stack comprises a dynamic random access memory (DRAM) bit line stack, and wherein the predicted end-of-line performance metric value comprises a sensing margin value.

18. The method of claim 12, wherein determining the target second thickness for the second layer of the multi-layer stack comprises:
inputting the first thickness of the first layer into a trained machine learning model that has been trained to output, for an input of the first thickness of the first layer, the target second thickness of the second layer that, when combined with the first thickness of the first layer, results in a predicted optimal end-of-line performance metric value for a device comprising the multi-layer stack.

19. The method of claim 18, wherein the trained machine learning model comprises a neural network.

20. The method of claim 18, wherein the trained machine learning model is further trained to output at least one of a target third thickness of a third layer of the multi-layer stack or an end-of-line performance metric value for a device comprising the multi-layer stack.

21. The method of claim 18, further comprising:
receiving an actual end-of-line performance metric value for the device comprising the multi-layer stack; and
retraining the trained machine learning model using a training data item comprising the first thickness of the first layer and the target second thickness of the second layer, the training data item further comprising a label that corresponds to the actual end-of-line performance metric value.

22. The method of claim 12, wherein the optical sensor is a component of a transfer chamber, a load lock chamber or a pass-through station connected to the transfer chamber, and wherein the first layer and the second layer are formed on the substrate without removing the substrate from a cluster tool comprising the first process chamber, the second process chamber and a transfer chamber connected to the first process chamber and the second process chamber.

23. A method comprising:
receiving or generating a training dataset comprising a plurality of data items, each data item of the plurality of data items comprising a combination of layer thicknesses for a plurality of layers of a multi-layer stack and an end-of-line performance metric value for a device comprising the multi-layer stack; and
training, based on the training dataset, a machine learning model to receive a thickness of a single layer or thicknesses of at least two layers of the multi-layer stack as an input and to output at least one of a target thickness of a single remaining layer of the multi-layer stack, target thicknesses for at least two remaining layers of the multi-layer stack or a predicted end-of-line performance metric value for a device comprising the multi-layer stack.

24. The method of claim 23, further comprising generating the training dataset by:
forming a plurality of versions of the multi-layer stack, each of the plurality of versions comprising a different combination of layer thicknesses for the plurality of layers of the multi-layer stack;
for each version of the multi-layer stack, manufacturing a device comprising the version of the multi-layer stack;
for each device comprising a version of the multi-layer stack, measuring an end-of-line performance metric to determine an end-of-line performance metric value; and
for each version of the multi-layer stack, associating the combination of layer thicknesses for the plurality of layers of the multi-layer stack with the end-of-line performance metric value.

25. The method of claim 23, wherein the multi-layer stack comprises a dynamic random access memory (DRAM) bit line stack, and wherein the predicted end-of-line performance metric value comprises a sensing margin value.
